(19) United States
(12) Patent Application Publication
(10) Pub. No.: US 2026/0221402 A1
(43) Pub. Date: Jul. 30, 2026

(54) Radical Sensing for Process Tool Diagnostics

(71) Applicant: MKS INSTRUMENTS, INC., Andover, MA (US)

(72) Inventors: Jimmy Liu, San Jose, CA (US); Chenglong Yang, Fremont, CA (US); James Blessing, Morgan Hill, CA (US); Keith K. Koai, Acton, MA (US); Guy Rosenzweig, Cambridge, MA (US); Amanda Larson, Medford, MA (US)

(73) Assignee: MKS INSTRUMENTS, INC., Andover, MA (US)

(21) Appl. No.: 19/143,073

(22) PCT Filed: Nov. 6, 2023
(86) PCT No.: PCT/US2023/078814

§ 371 Date: Jun. 25, 2025

Related U.S. Application Data
(60) Provisional application No. 63/383,955, filed on Nov. 16, 2022.

(51) Int. Cl. H01J 37/32

(52) U.S. Cl. CPC H01J 37/3299; H01J 37/32853; H01J 37/3288; H01J 37/32926; H01J 37/32972

(57) ABSTRACT

An apparatus and technique for measuring a concentration of radical particles within a gas sample obtained from a location within a semiconductor processing system having a process chamber while a process is being performed within the process chamber includes obtaining radical data corresponding to the measured concentration of radical particles, comparing the obtained radical data to at least one threshold and outputting a control signal when a result of the comparing indicates that the obtained radical data has a predetermined relationship with the at least one threshold. The first control signal can be configured to cause a chamber recovery process to be performed within the process chamber or indicate that a chamber recovery process should be performed within the process chamber.

### BACKGROUND

### I. Technical Field

Embodiments of the present invention relate generally to semiconductor processes and, more particularly, to semiconductor processes with radicals generated by a remote plasma source or other plasma/thermal radical generation sources. Even more particularly, embodiments of the present invention relate to methods of performing conditioning/seasoning or preventive maintenance (PM) for a radical generation plasma source and process chamber when applying radicals for on-wafer processes.

### II. Discussion of the Related Art

Semiconductor processing typically takes place in specialized semiconductor processing system. The system often includes a semiconductor process chamber that houses a wafer during processing. The semiconductor processing system also typically includes various pieces of hardware (e.g., a substrate support, showerhead, throttle valve, etc.) arranged within or connected to the semiconductor processing chamber for accomplishing the semiconductor fabrication processes.

Various semiconductor fabrication processes involve the use of a remote plasma source or other plasma sources such as Inductively Coupled Plasma (ICP), Capacitively Coupled Plasma (CCP), Transformer Coupled Plasma (TCP), etc., to generate active species e.g., radicals, ions, etc., to which a substrate can be beneficially exposed during processing. Remote plasmas can be desirable in some situations because they can provide a relatively high concentration of radicals and a relatively low concentration of ions (or no ions), compared to plasmas that are generated directly in a semiconductor process chamber (e.g., via a ICP, CCP or TCP source). Thus, it is particularly useful to use a remote plasma when it is desired that processing occurs by way of radicals.

One problem encountered with processing with radicals is that of reduction of delivered radical flux at the substrate. The delivered radical flux can be reduced due to variations in plasma source output and transfer losses such as recombination due to various wetted interior surfaces of the semiconductor processing system and chemistries thereof. If radicals recombine before reaching the substrate, such radicals are no longer available for processing on the substrate. Certain radicals (e.g., hydrogen radicals, oxygen radicals and nitrogen radicals) experience this problem to a greater degree than other radicals. Indeed, hydrogen radicals have very high recombination rates on most materials. The result is that when processing a substrate using remotely generated radicals (e.g., of hydrogen, oxygen and nitrogen), the radicals often recombine in a part of the plasma source chamber, on surfaces between the plasma source and the semiconductor process chamber and/or on internal surfaces of the semiconductor process chamber (e.g., during set-up of the chamber), which leaves these radicals incapable of performing consistently or repeatably on the substrate. Yield loss and increased cost-of-ownership from reduced radical flux can become high if not corrected. For a given process recipe (e.g., consisting of a predetermined gas flow, pressure, temperature, power, etc.), the radicals delivered to the substrate within a semiconductor process chamber can be affected by radicals generated the plasma sources(s) that are part of the semiconductor processing system, the wetted surface conditions and chemistries of interior surfaces of the semiconductor processing system (e.g., interior surfaces of the semiconductor process chamber, substrate support, showerhead, etc.), the radical transport surface conditions in a semiconductor process chamber set-up, etc. Thus, radical recombination can occur after an initial set-up of the semiconductor processing system (i.e., before any device wafers have been processed), after the interior of a semiconductor process chamber (and components mounted therein) has been cleaned, after process recipes used within the semiconductor process chamber have changed, and the like.

To reduce radical recombination, a conditioning or seasoning process may be performed based upon the wetted materials of the interior surfaces in the semiconductor processing system with which radicals interface. During a conditioning/seasoning process, a series of dummy wafers are processed through the process chamber according to a predetermined conditioning/seasoning recipe. The dummy wafers are typically similar to device wafers used during regular production within the semiconductor process chamber and, likewise, the conditioning recipe is similar or identical to the actually process recipe used during production in the semiconductor process chamber. The objective of conditioning/seasoning is to passivate, by subjecting a series of dummy wafers to a conditioning recipe, an initial layer of material on the interior surfaces of the semiconductor process chamber and any other interior surfaces associated with the semiconductor processing system. If the chamber is not conditioned in this way, the first number of production wafers experience significantly different process conditions, resulting in yield loss. Typically, the number of dummy wafers that need to be subjected to the processing recipe is predetermined, or may be determined by performing post-processing inspection of the dummy wafers and/or interior of the semiconductor process chamber. However, these methods rely on a technician's experience and expertise, which may be undesirably variable depending on the technician developing the conditioning/seasoning protocol and may not be able to account for novel sources of contamination.

### SUMMARY

One embodiment of the present invention can be generally characterized as an apparatus that includes a controller for use with a radical particle monitor operative to measure a concentration of radical particles within a gas sample obtained from a location within a semiconductor processing system having a process chamber while a process is being performed within the process chamber. The controller can be configured to obtain radical data corresponding to a measured concentration of radical particles, compare the obtained radical data to at least one threshold and output a first control signal when a result of the comparing indicates that the obtained radical data has a predetermined relationship with the at least one threshold. The first control signal can be configured to cause a chamber recovery process to be performed within the process chamber or indicate that a chamber recovery process should be performed within the process chamber. Another embodiment of the present invention can be generally characterized as tangible computer-readable media having instructions stored thereon which, when executed by a processor of the aforementioned controller, causes the controller to perform the acts recited therein.

Another embodiment of the present invention can be generally characterized as a method that includes measuring a concentration of radical particles within a gas sample obtained from a location within a semiconductor processing system having a process chamber while a process is being performed within the process chamber, obtaining radical data corresponding to the measured concentration of radical particles, comparing the obtained radical data to at least one threshold and outputting a first control signal when a result of the comparing indicates that the obtained radical data has a predetermined relationship with the at least one threshold. The first control signal can be configured to cause a chamber recovery process to be performed within the process chamber or indicate that a chamber recovery process should be performed within the process chamber.

### BRIEF DESCRIPTION OF THE DRAWINGS

FIGS. 1A-1C are diagrams of semiconductor processing systems implementing a radical particle monitor in example embodiments.

FIGS. 2A and 2B are diagrams of semiconductor processing systems implementing a radical particle monitor in further embodiments.

FIG. 3A is a diagram of a radical particle monitor according to some example embodiments.

FIG. 3B is a diagram schematically illustrating various communication schemes by which components of the semiconductor processing system and radical particle monitor can communicate.

FIGS. 4A-4C are diagrams of a subset of a radical particle monitor in example embodiments.

FIGS. 5A-5C are diagrams of inlet ports that can be implemented with a radical particle monitor.

FIGS. 5A-5C are diagrams of inlet ports that can be implemented with a radical particle monitor.

FIGS. 6A-6B are diagrams of inlet ports configured for a bias voltage or temperature control.

FIGS. 7A-7C illustrate example configurations implementing an aperture stopper.

FIG. 8 is a diagram of a subset of a radical particle monitor in a further configuration.

FIGS. 9 and 10 are flow diagrams of processes involving monitoring radical particle concentration according to some example embodiments of the present invention.

### DETAILED DESCRIPTION

Example embodiments are described herein with reference to the accompanying FIGS. Unless otherwise expressly stated, in the drawings the sizes, positions, etc., of components, features, elements, etc., as well as any distances therebetween, are not necessarily to scale, but are exaggerated for clarity.

The terminology used herein is for the purpose of describing particular example embodiments only and is not intended to be limiting. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first node” and similarly, another node could be termed a “second node”, or vice versa. The section headings used herein are for organizational purposes only and are not to be construed as limiting the subject matter described.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Spatially relative terms, such as “below,” “beneath,” “lower,” “above,” and “upper,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

Like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

It will be appreciated that many different forms and embodiments are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

Embodiments of the present invention provide a radical sensing capability to quantitatively monitor the radical flux within a semiconductor processing system at one or more locations therein and provide feedback, which can be used for the process tool diagnostics and improve the process tool cost-of-ownership, such as ensuring unit to unit, chamber to chamber matching, timely initiate seasoning/conditioning recipes (e.g., to prevent process drift out of the predetermined process windows); or timely initiating preventative maintenance (PM) activities (e.g., if the radical generation source or the process chamber parts exposed to the radical delivery path that has reached its lifetime, etc.).

### I. Embodiments Concerning Semiconductor Processing Systems, Generally

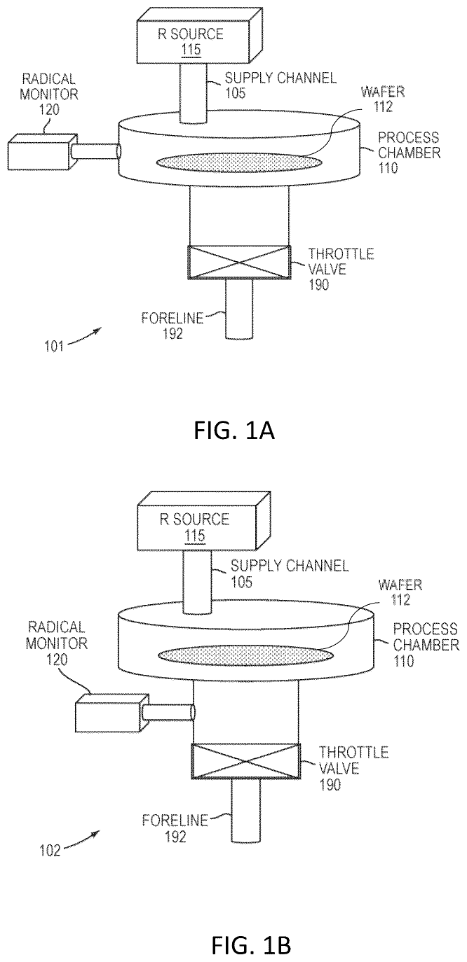

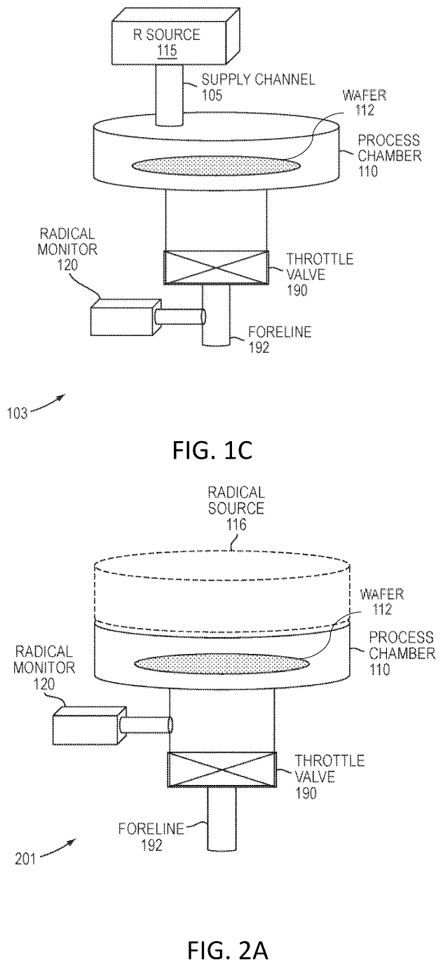

FIGS. 1A-1C are diagrams of semiconductor processing systems implementing a radical particle monitor according to some embodiments. FIGS. 2A-2B are diagrams of semiconductor processing systems implementing a radical particle monitor according to other embodiments.

Referring to FIG. 1A, a semiconductor processing system 101, according to some embodiments, can include radical particle monitor 120 (also referred to herein as a “radical monitor” or “RPM”). The system 101 includes a semiconductor process chamber 110 in which a semiconductor wafer 112 is processed, such as in etching and/or deposition processes. To facilitate this processing, a radical source 115, such as a remote plasma source (RPS), a capacitively coupled plasma source (CCP), an inductively coupled plasma source (ICP), a transformer coupled plasma source (TCP), etc., can emit a gas into the semiconductor process chamber 110 via a supply channel 105, which may be straight, curved, or angled, such as an elbow. Depending on the desired process, the gas may have one of a number of different compositions of stable particles, radical particles, and ions (e.g., a plasma gas). A throttle valve 190 can be selectively opened to pass the gas from the semiconductor process chamber 110 to a foreline 192, wherein the gas may then be exhausted from the system 100 or collected for further use.

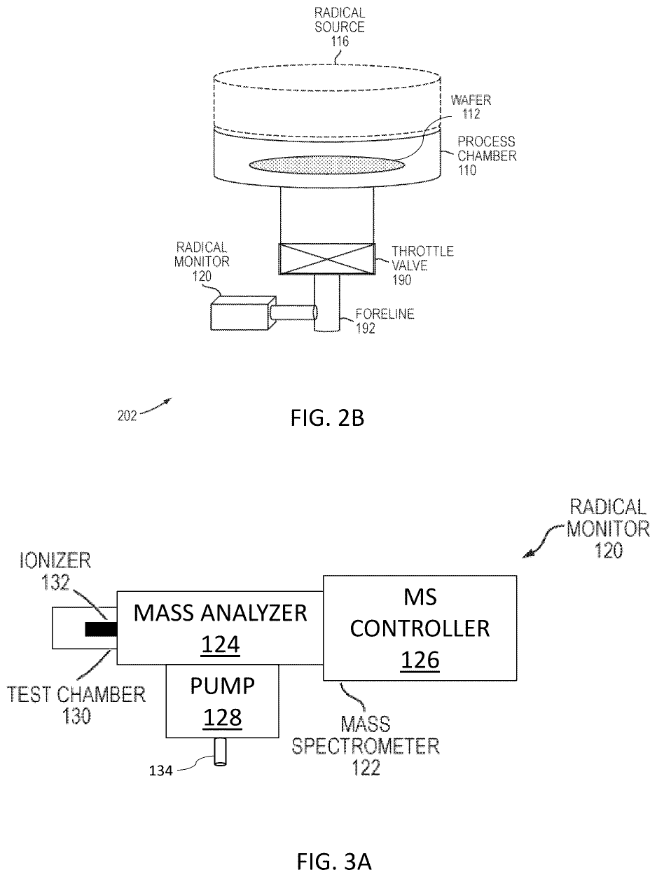

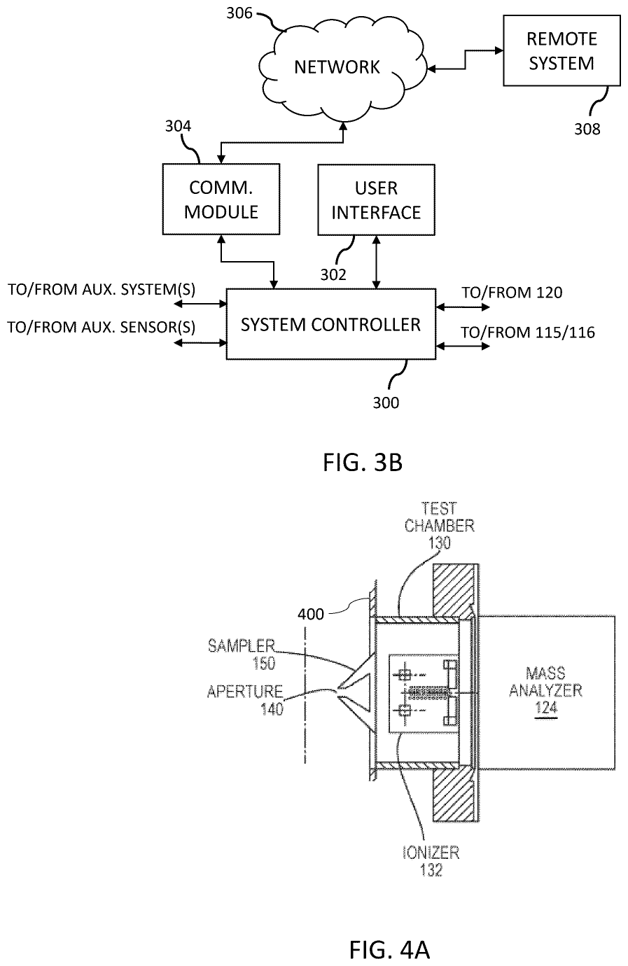

The racial particle monitor (RPM) 120 operates to monitor the presence of radical particles in the gas. As schematically shown in FIG. 3A, the RPM 120 may include a test chamber 130, an ionizer 132, and a mass spectrometer 122. The test chamber 130 may be coupled to a gas flow channel, such as the semiconductor process chamber 110, as shown in FIG. 1A (or the foreline 192, e.g., as shown in FIG. 1B or 1C), to receive a subset of the gas to the test chamber 130.

The ionizer 132, positioned within the test chamber 130, may be configured to ionize the radical particles of the subset of the gas to generate radical ions within the test chamber 130. The mass spectrometer 122 may be a residual gas analyzer (RGA) or comparable system, and may include a mass analyzer 124, a radical monitor controller 126, and a pump 128. The mass analyzer 124 may receive the radical ions from the ionizer 132 and perform mass filtering and ion detection on the radical ions to measure the presence of the radical ions. The radical monitor controller 126 may then receive data representing the measurements from the mass analyzer 124, as is known in the art, and process the measurements from the mass analyzer 124 to generate corresponding radical data (e.g., representing information such as type and quantity of radical ions in the gas) or other data or signals, as will be described in greater detail below. The pump 128 (e.g., a vacuum or turbo pump) can operate to pump gas from the mass analyzer 124 and/or test chamber 130 to maintain the test chamber 130 at an appropriate pressure (e.g., less than 1e-2 torr), transferring the gas (e.g., via conduit 134) to the foreline 192 or another exhaust.

In general, the test chamber 130 may be adapted to capture an optimal sample of the gas while minimizing reaction of the radical particles that enter the test chamber 130. The ionizer 132 may also be configured to maximize ionization of the radical particles that enter the test chamber 130, directly. Further, the mass spectrometer 122 may operate in one or more low energy states to ionize and measure the radical particles without interference from non-radical particles. The RPM 120 may be further configured to provide multiple modes of operation to detect and measure the presence of different radical particles, as well as the presence of non-radical particles, e.g., by operating in different energy states. It will be appreciated that different radical particles may be ionized at different energy states. For example, the ionizer 132 may ionize N radicals at 24 eV, while fluorine radicals require at a different energy state of 21 eV for ionization. Thus, if it is desired to measure the quantity of multiple different radicals in the gas, then a sample may captured within the test chamber 130 may be sequentially ionized by the ionizer 132 at different energy levels. For example, the ionizer 132 may be set to ionize N radicals in a first sample at 24 eV, and then modify the energy level of the ionizer to measure H radicals at 16 eV. The process may then be repeated multiple additional times, in rapid succession, to measure the quantity of different radical particles (e.g., radical particles of N, O, OH, F, H, Cl, NHx, CHx, NxOy, etc.). Thus, the ionizer 132 may operate at a plurality of low-energy states, each of the plurality of low-energy states corresponding to a respective radical particle so that the RPM 120 can provide for reliable measurement of radical particles within a gas.

Referring to FIGS. 1B and 1C, the systems shown therein may incorporate some or all features of the system 101 described above, except that they may implement a radical particle monitor in different configurations. For example, FIG. 1B shows a system 102 wherein the RPM 120 is coupled to a wall of the foreline 192 above the throttle valve 190 while FIG. 1C shows a system 103 wherein the RPM 120 is coupled to a wall of the foreline 192 below the throttle valve 190.

Referring to FIGS. 2A and 2B, the systems 201 and 202 may incorporate some or all features of the system 101 described above, except that they implement a radical particle source 116, such as a capacitively coupled plasma source (CCP), or an inductively coupled plasma source (ICP), a transformer coupled plasma source (TCP), etc., in place of (or in addition to) the radical source 115. The radical particle source 116 may occupy an upper volume of the semiconductor process chamber 110, or may be contained in a separate chamber adjacent to the semiconductor process chamber 110. Due to this configuration, the supply channel 105 may be omitted. Accordingly, the RPM 120 may be coupled to a wall of the foreline 192 above the throttle valve 190 as shown in FIG. 2A, or may be coupled to the foreline 192 below the throttle valve 190 as shown in FIG. 2B. Alternatively, and although not illustrated, the RPM 120 may be coupled to a wall of the semiconductor process chamber 110.

For a given gas transmitted through any of the systems 101-103, 201 or 202, the gas sampled by the RPM 120 may differ due to where the sample is collected. The concentration of radical particles within the sampled gas (i.e., the quantity of radical particles in the sampled gas) is likely to diminish as a function of distance of the RPM 120 from the radical source 115 or 116. Furthermore, the concentration of background gas and other particles may be altered after interacting with the wafer 112 and the interior surfaces (e.g., of the semiconductor process chamber 110, throttle valve 190, the foreline 192, etc.) confining the gas. For these reasons, the RPM 120 may be calibrated based on the sampling location, and/or the measurements of the radical particles and other particles provided by the RPM 120 may be calculated based on the sampling location.

Although not illustrated in FIG. 1A-1C or 2A-2B, each of the semiconductor processing systems 101-103 and 201-202 may further include one or more vacuum pumps, mass flow controllers, heating systems, cooling systems, etc. (each generically referred to herein as an “auxiliary system”), to control or otherwise influence the pressure, temperature, gas composition, etc., within the processing chamber as is known in the art. Likewise, the aforementioned semiconductor processing systems may include one or more auxiliary sensors (e.g., one or more temperature sensors, pressure sensors, or the like or any combination thereof, as is known in the art) configured to sense or monitor at least one condition (e.g., temperature, pressure, etc.) within the processing chamber.

Further, and although not illustrated in FIG. 1A-1C or 2A-2B, the aforementioned semiconductor processing systems may include a system controller communicatively coupled to the RPM 120 and, optionally, to the radical source 115 or 116, throttle valve 190, any of the aforementioned auxiliary systems, any of the auxiliary sensors, or any combination thereof, to control, or facilitate control of, operation of the semiconductor processing system.

Referring to FIG. 3B, the system controller 300 can be communicatively coupled (e.g., over one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof) to one or more components of the aforementioned components of the semiconductor processing system (e.g., the RPM 120, radical source 115 or 116, throttle valve 190, any of the aforementioned auxiliary systems, any of the auxiliary sensors, etc.). Such components are, therefore, operative in response to one or more control signals generated and output by the system controller 300.

Generally, the system controller 300 (and, likewise, the radical monitor controller 126) includes one or more processors operative to generate the aforementioned control signals upon executing instructions. A processor can be provided as a programmable processor (e.g., including one or more general purpose computer processors, microprocessors, digital signal processors, or any other suitable form of circuitry including programmable logic devices (PLDs), field-programmable gate arrays (FPGAs), field-programmable object arrays (FPOAs), application-specific integrated circuits (ASICs)—including digital, analog and mixed analog/digital circuitry—or the like, or any combination thereof) operative to execute the instructions. Execution of instructions can be performed on one processor, distributed among processors, made parallel across processors within a device or across a network of devices, or the like or any combination thereof.

In one embodiment, the system controller 300 (and, likewise, the radical monitor controller 126) includes tangible media such as computer memory, which is accessible (e.g., via one or more wired or wireless communications links) by the processor. As used herein, computer memory (or, more simply, “memory”) includes magnetic media (e.g., magnetic tape, hard disk drive, etc.), optical discs, volatile or non-volatile semiconductor memory (e.g., RAM, ROM, NAND-type flash memory, NOR-type flash memory, SONOS memory, etc.), etc., and may be accessed locally, remotely (e.g., across a network), or a combination thereof. Generally, the instructions may be stored as computer software (e.g., executable code, files, instructions, etc., library files, etc.), which can be readily authored by artisans, from the descriptions provided herein, e.g., written in C, C++, Visual Basic, Java, Python, Tel, Perl, Scheme, Ruby, assembly language, hardware description language (e.g., VHDL, VERILOG, etc.), etc. Computer software is commonly stored in one or more data structures conveyed by computer memory.

Referring to FIG. 3B, the aforementioned semiconductor processing systems may include a user interface 302 communicatively coupled to the system controller 300 (e.g., over one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof). The user interface 302 can include one or more output devices, one or more input devices, or any combination thereof. Generally, an output device is any device capable of rendering or otherwise conveying information through any human-perceptible stimuli (e.g., visual, audible, tactile, etc.). Examples of output devices include monitor, a printer, a speaker, a haptic actuator, and the like. Generally, an input device is any device that enables, e.g., a user of the semiconductor processing system, to provide instructions, commands, parameters, information, or the like, to operate the semiconductor processing system (or to facilitate operation of the semiconductor processing system). Examples of input devices include a keyboard, mouse, touchpad, touchscreen, microphone, a camera, and the like.

Optionally and with continued reference to FIG. 3B, the semiconductor processing system includes a communications module 304 communicatively coupled to the system controller 300 (e.g., over one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof). The communications module 304 is operative to transmit data, receive data, or a combination thereof. Accordingly, the communications module 304 can include circuitry, antennas, connectors, or the like or any combination thereof, to transmit and/or receive data through a wired or wireless link to another device or network (e.g., network 306). In one example, the communications module 304 can be a connector that operates in conjunction with software or firmware in the system controller 300 to function as a serial port (e.g., RS232), a Universal Serial Bus (USB) port, an IR interface or the like or any combination thereof. In another example, the communications module 304 can be a universal interface driver application specific integrated circuit (UIDA) that supports plural different host interface protocols, such as RS-232C, IBM46XX, Keyboard Wedge interface, or the like or any combination thereof. The communications module 122 may include one or more modules, circuits, antennas, connectors, or the like, as known in the art, to support other known communication modes, such as USB, Ethernet, Bluetooth, wifi, infrared (e.g., IrDa), RFID communication, or the like or any combination thereof. Instead of being a separate component from the system controller 300, it will be appreciated that the communications module 304 may be incorporated as part of the system controller 300 in any known or suitable manner.

The network 306 may be communicatively coupled (e.g., over one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof) to one or more systems remote to the semiconductor processing system (e.g., to remote system 308, as identified in FIG. 3B). In one embodiment, the remote system 308 may be a device such as a computer (e.g., a desktop computer, a laptop computer, a tablet computer, a smartphone, etc.), a computing system (e.g., a cloud computing platform), another controller or communications module (e.g., associated with another semiconductor processing system), or the like or any combination thereof. It should be appreciated that the remote system 308 may include, or otherwise be coupled to, a user interface that includes one or more output devices, one or more input devices, or any combination thereof, as exemplarily described above with respect to the user interface 302. The remote system 308 can be a device owned or otherwise operated by a user of the semiconductor processing system, by a manufacturer of the semiconductor processing system or any component thereof (e.g., the RPM 120, the radical source 115 or 116, etc.), by a technician responsible for performing maintenance on the semiconductor processing system, or the like or any combination thereof.

Through the communications module 304 and network 306, the system controller 300 may communicate various data to the remote system 308. Examples of data that can thus be output to the remote system 126 include the aforementioned radical data or any other data generated by the radical source 115 or 116, any of the auxiliary systems, any of the auxiliary sensors, or the like or any combination thereof. Data output by the remote system 308 may be input to the system controller 300 (e.g., via the network 306 and communications module 304) and represent instructions, commands, parameters, information, or the like, to operate the semiconductor processing system or to otherwise influence or facilitate any operation of the semiconductor processing system.

According to the embodiments described thus far, the radical monitor controller 126 are the system controller 300 are physically distinct components communicatively coupled to one another by one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof. In an alternative embodiment, the functionality provided by the radical monitor 126 may be provided by the system controller 300. In this alternative embodiment, the system controller 300 may be communicatively coupled to the output of the mass analyzer 124 (e.g., to receive data representing the measurements from the mass analyzer 124, as is known in the art).

### II. Embodiments Concerning Radical Particle Monitor

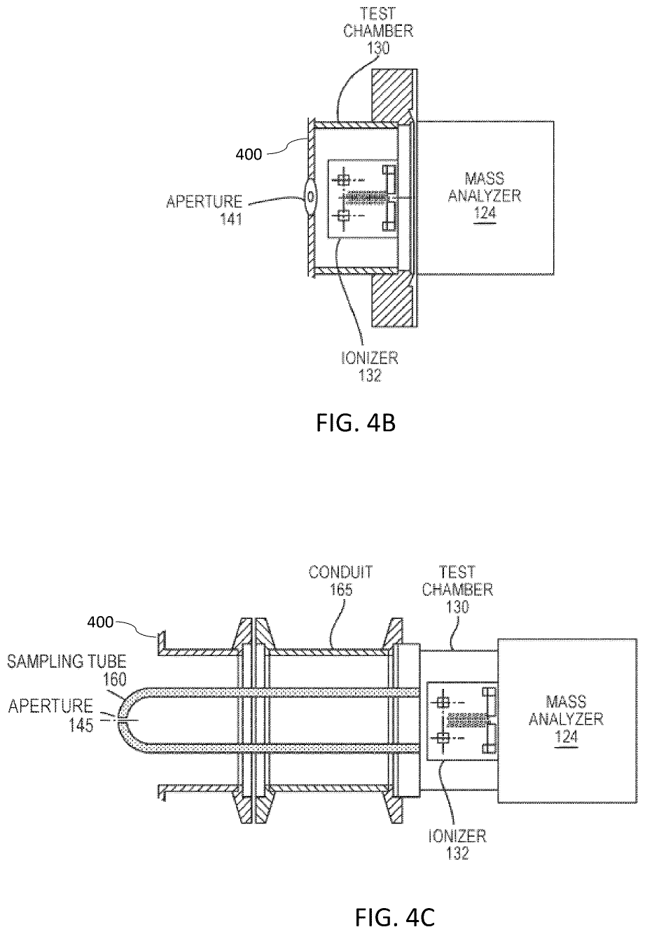

FIG. 4A illustrates a portion of the RPM 120 in further detail. Here, the test chamber 130 is shown to be in gaseous communication with the gas flow channel via an aperture 140. Reference numeral 400 designates a wall of the gas flow channel (i.e., either the semiconductor process chamber 110 or foreline 192, as variously shown in FIGS. 1A-1C, 2A and 2B). The aperture 140 may be sized such that it enables passage of an acceptable number of radical particles without reaction, while also maintaining a low gas pressure within the test chamber to facilitate particle detection. For example, if the mass analyzer 124 is configured as an RGA, then the test chamber 130 may be required to maintain a pressure of less than 1e-2 torr, despite the supply channel maintaining a pressure in the range of 0.01-10 torr. In such an application, the aperture 140 may have a diameter of less than 1 millimeter, and, in one example, may have a diameter of approximately 35 μm. The aperture 140, configured as described herein, may permit passage, to the test chamber 130, a quantity of the radical particles that is suitable for detection by the mass spectrometer 122 without excessive losses. This result may be expressed as a ratio of radical particles to non-radical particles that is present in the gas in the test chamber 130 in contrast to the ratio present in the gas in the gas flow channel. For example, the aperture 140 may permit passage, to the test chamber 130, a ratio of radical particles to non-radical particles that is greater than 0.1% of the ratio present in the gas within the gas flow channel. In further embodiments, the ratio present in the test chamber 130 may be 1% or greater than the ratio present in the gas flow channel to which the test chamber 130 is coupled, such as the semiconductor process chamber 110 or foreline 192 as shown in FIGS. 1A-1C, 2A and 2B.

When radical particles are transported through the gas flow channel, the radicals near the wall 400 of the gas flow channel may collide with the wall 400 surface frequently, having a high recombination rate and leading to the loss of the radical particles. Therefore, the density of the radical particles near the wall 400 may be relatively low and not representative of the true population of radical particles being delivered from the radical source 115 or 116. Thus, sampling the radical particles near the wall 400 of the gas flow channel with an aperture on the wall 400, as described below, may not have an optimal efficiency of radical sampling.

A cone-shaped sampler 150, with the aperture 140 positioned at the end of the sampler 150, extends the sample point nearer to the center of the gas flow channel from the radical source 115 or 116, where the species sampled may have experienced fewer surface collisions. Such a sampling location may have the much higher radical density than a sampling location at the wall 400 of the gas flow channel. Further, the ionizer 132 may be positioned in close proximity to the sampler 150 (e.g., within 4 inches, and within 0.5 inches in the example shown) to increase detection sensitivity by intercepting a larger fraction of the line-of-sight cone of radicals expanding into the test chamber 130 after passing through the aperture 140. The conical shape of the sampler 150 also minimizes collisions with radical particles that pass through the aperture 140 by allowing the particles a wider path at the entrance of the test chamber 130. Alternatively, the sampler 150 may form a protrusion defining one of a range of different shapes, such as a semi-sphere, a cylinder, a prism, or an elliptical or oval shape. In such alternatives, the protrusion may extend into the gas flow channel, and may encompass a volume of the test chamber 130, wherein the aperture 140 is positioned at an end or another surface of the protrusion. Alternatively, the sampler 150 may partially or fully recessed from the wall of the gas flow channel. Recessing the sampler 150 may be advantageous in applications where proximity to the gas flow channel is limited, meaning that the components of the RPM 120 (e.g., ionizer 132 and/or mass spectrometer 122) must be positioned some distance from the gas flow channel. Recessing the sampler 150 may provide additional advantages, such as reducing interference with the gas flow through the gas flow channel and positioning the aperture 142 closer to the ionizer 132 to increase the quantity of ionized radical particles in the test chamber 130.

The sampler 150 may have a non-metal surface composed of glass, quartz, sapphire, SiO₂, Al₂O₃, or another material that exhibits a low recombination rate (relative to metal surfaces) with a given set of radical particles to be measured, such as radical particles of H, N, O, OH, NHₓ, CHₓ, and NO. Alternatively, the sampler 150 may have a metal surface composed of aluminum or stainless steel or aluminum nitride or aluminum oxide, or another material that exhibits a low reaction rate (relative to non-metal surfaces) with a given set of radical particles to be measured, such as radical particles of F, Cl, NFₓ, and CFₓ.

The above features, along with a high vacuum (e.g., 1e-5 torr) in the test chamber 130, can enable a long mean free path for particles within the test chamber 130. Thus, a large portion of the radical particles that travel through the aperture 140 will reach the ionizer 132 before colliding with a wall or another particle, leading to a higher chance of radical ionization. A combination of some or all of the above features, including extending the aperture 140 into the gas flow channel, enabling clearance for free radicals via the cone-shaped sampler 150, and positioning the ionizer 132 close to aperture 140, can enable the ionizer 132 to generate more radical ions from the radical particles, thereby providing the mass analyzer 124 with greater sensitivity for radical detection.

FIGS. 4B and 4C illustrate a portion of the RPM 120 in further embodiments. The embodiments may include some or all features of the RPM 120 described above with reference to FIGS. 1A-4A, with the exception that the interface between the gas flow channel and the test chamber 130 is configured as described below. FIG. 4B shows a configuration wherein the test chamber 130 and gas flow channel share a common wall 400, and wherein an aperture 141 is located at the common wall 400 without protrusion into the gas flow channel. The aperture 141 may be a prefabricated surface (e.g., a stainless-steel gasket) with an orifice that is installed (e.g., welded) at a larger opening in the common wall. Alternatively, the aperture 141 may be a simple orifice that is drilled through the common wall 400.

FIG. 4C shows a sampling arrangement in a further configuration. Here, a sampling tube 160 is implemented in place of a sampler as shown in FIGS. 4A and 4B. This configuration may be advantageous when some or all of the RPM 120 must be positioned farther away from the gas flow channel to be sampled. The sampling tube 160 may extend partially into the gas flow of the gas flow channel as shown, and may extend a distance within a conduit 165 before opening into the test chamber 130. To facilitate transporting radical particles along the interior volume of the sampling tube 160, the sampling tube 160 may be composed of (or coated with) a material that has low reactivity or recombination rate with the radical particle(s) to be measured. For example, the sampling tube 160 may have an interior surface of quartz or sapphire, which exhibit a low recombination rate with N and H radical particles. Alternatively, the sampling tube 160 may have a surface composed of aluminum, stainless steel, glass or comparable material, wherein different surfaces may optimal for minimizing reactions of a given set of radical particles.

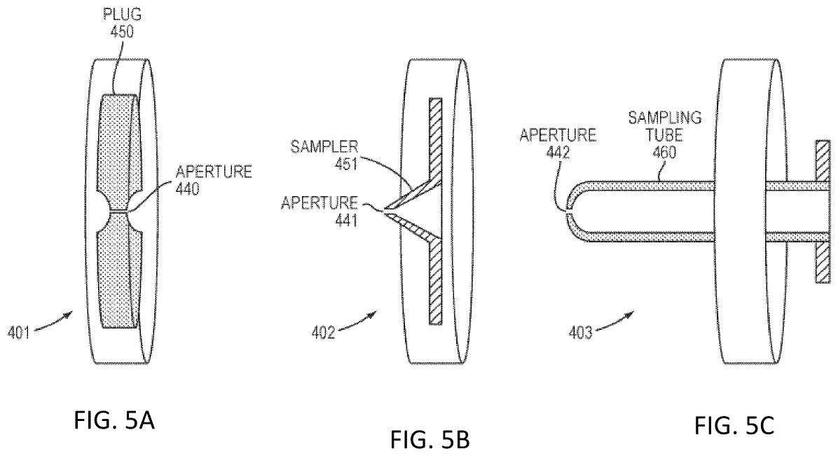

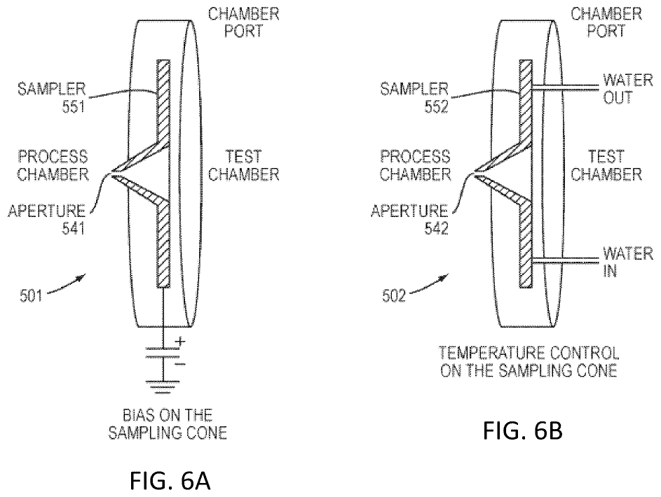

FIGS. 5A-5C illustrate prefabricated inlet ports 401-403 that can be implemented with a radical particle monitor such as RPM 120. The ports 401-403 can be positioned between a gas flow channel and a test chamber, such as in the embodiments described above with reference to FIGS. 1A-4C, to control the flow of a subset of gas in the gas flow channel into the test chamber. The port 401 includes a cylindrical plug 450 having an aperture 440 through its center. The aperture 440 may be sized and configured as other apertures described above, and, as shown, may include one or more recesses at one or both sides of the plug 450, which may enable a greater flow of radical particles without reaction. The port 402 includes a sampler 450 defining a disc shape and having a conical shape toward its center, wherein the aperture 441 occupies the end of the conical shape. The sampler 441 may be configured comparably to other samplers described above. The port 403 includes a sampling tube 460 that extends through the port (e.g., a cylindrical plug as in the port 401) and terminates with an aperture 442. The sampling tube 460 may include some or all features of the sampling tube 160 described above with reference to FIG. 4C. Each of the ports 401-403 may be composed of any material suitable for gas transport and vacuum applications, such as stainless steel, and may have one or more surfaces comprised of a material having a low recombination rate and reactions with target radical particles as described above.

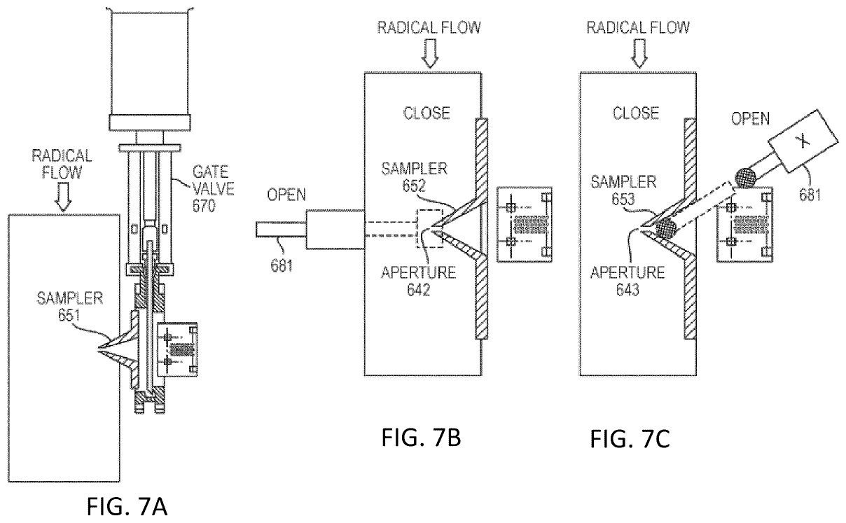

FIGS. 6A-6B illustrate inlet ports 501, 502 configured for bias voltage and temperature control features, respectively. At FIG. 6A, the inlet port 501 includes a sampler 551 that is electrically conductive and is coupled to a bias voltage. The bias voltage may cause the sampler 551 to exhibit a charge that repels certain ions and thereby reduces passage of those ions through the aperture 541, reducing ion interference in the adjacent test chamber. The bias voltage can be a positive or negative voltage depending on the targeted ions. For example, a positive bias voltage can repel positive ions such as nitrogen ions (N⁺), which would interfere with the measurement of nitrogen radical particles. Alternatively, a negative bias voltage can repel negative ions such as fluorine ions (F⁻), which would interfere with the measurement of fluorine radical particles.

Turning to FIG. 6B, the inlet port 502 includes a sampler 552 having one or more internal conduits that are adapted to pass a flow or water or other liquid through the sampler 552, thereby cooling (or, alternatively, heating) the sampler 552 towards a target temperature. During operation of RPM 120, radical recombination at the surface of the sampler 552 can impart heat to the sampler 552, raising its temperature and increasing the rate of recombination with subsequent radical particles. By directing a coolant through the sampler 552, the sampler 552 can be maintained at a lower temperature, thereby reducing its recombination rate with radical particles. In further embodiments, a sampler may combine the bias voltage and temperature control features of the samplers 551, 552.

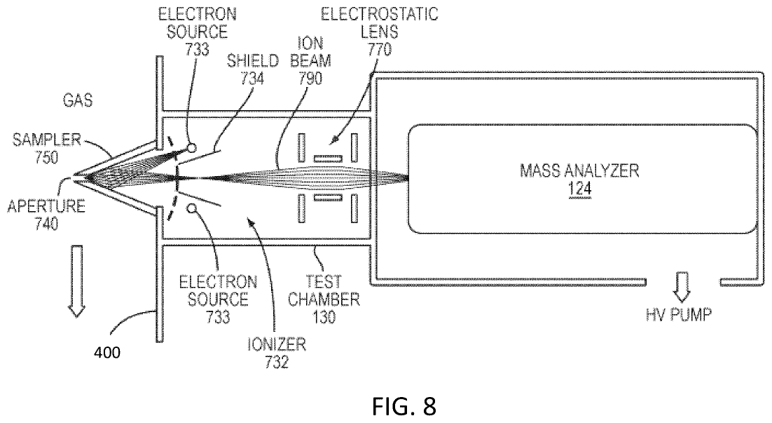

FIGS. 7A-7C illustrate example configurations implementing an aperture stopper. When RPM 120 is not in operation, it may be advantageous to protect the RPM 120 by sealing the aperture between the gas flow channel and the test chamber, particularly if the gas pressure or temperature in the gas flow channel is raised significantly. Various mechanical means can be used to selectively seal the aperture. For example, as shown in FIG. 7A, a mechanical throttle valve 670 can be positioned between the sampler 651 and a test chamber. When the throttle valve 670 is actuated, it may form a seal between the sampler 651 and the test chamber, thereby preventing particles from entering the test chamber through the sampler. In FIG. 7B, an automated stopper 680 may reside in a recessed chamber of the gas flow channel opposite of the sampler 652. When actuated, the stopper 680 moves laterally to seal around the aperture 642, thereby sealing the gas flow channel from the test chamber opposite the sampler 652. Lastly, in FIG. 7C, illustrates an automated stopper 680 residing within or adjacent to a test chamber. When actuated, the stopper 681 moves toward the aperture 643 until it creates a seal with the sampler 653, thereby sealing the gas flow channel from the test chamber.

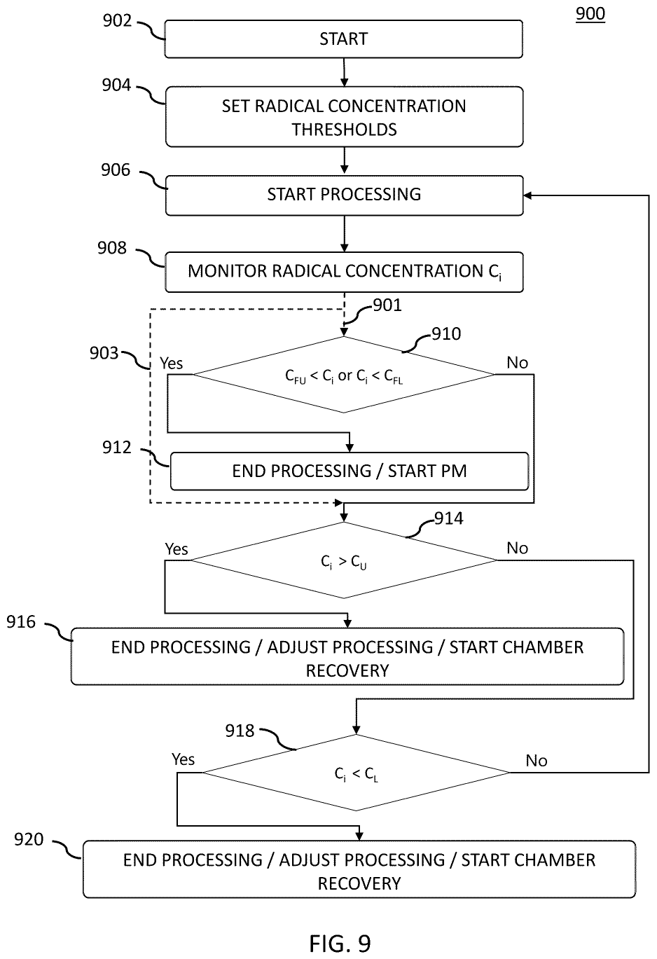

FIG. 8 illustrates a portion of an RPM in a further embodiment. The RPM shown in FIG. 8 may include some or all applicable features of the embodiments described above with reference to FIGS. 1A-7C, including a test chamber 130 coupled to a gas flow and a sampler 750 to divert a subset of the gas from the gas flow channel to the test chamber 130 via an aperture 740. In contrast to the embodiments above, an ionizer 732 is positioned close to the sampler 750 and is configured to ionize the radical particles within the volume defined by the sampler 750 and generate a beam of radical ions 790. To do so, the ionizer 732 may include electron sources 733 and a shield 734. The shield 734, shown in cross-section, may encompass two or more sides of the electron sources 733, and may include slits or orifices between the electron sources 733 and the sampler 750 to direct beams of electrons from the electron sources 733 into the volume of the sampler 750 to a region near the aperture 740.

The electron beams serve to ionize the radical particles within the volume of the sampler 750, generating the ion beam 790, which is directed through another opening in the shield 734 towards a mass analyzer 124 of the RPM. In this configuration, the conical shape of the sampler 750 may serve as an electrostatic element of the ionizer 732. The shield 734 may also encompass other sides of the electron sources 733 to divert electrons from the ion beam 790. The ion beam 790 extends towards the mass analyzer 124, and is focused into an inlet of the mass analyzer 124 by an electrostatic lens 770. The mass analyzer 124 may receive the radical ions of the ion beam 790 and perform mass filtering and ion detection on the radical ions to measure the presence of the radical ions. A controller (not shown, but provided as described above with respect to radical monitor controller 126 in FIG. 3A) may be communicatively coupled to the mass analyzer 124 (e.g., to receive data representing the measurements from the mass analyzer 124, as is known in the art).

### III. Embodiments Concerning Semiconductor Processing System Control Based on Radical Monitoring

In one embodiment, the radical data obtained by monitoring the radical particle concentration (e.g., using the RPM 120 according to any of the embodiments discussed above) is further processed (e.g., by the radical monitor controller 126 or the system controller 300, each generically referred to as a “controller”) to estimate the efficiency with which radicals are being delivered into the process chamber 110. For example, the controller may compare the radical quantity measured by the mass analyzer 124 (e.g., represented by certain generated radical data) against respective a threshold or target value. In this case, the controller can generate radical delivery efficiency data representing the estimated radical delivery efficiency by computing a ratio of the radical data corresponding to the measurement obtained by the mass analyzer 124 to data representing the threshold or target value. The radical delivery efficiency data may be stored within memory at the radical monitor controller 126 and/or the system controller 300. In one embodiment, the radical delivery efficiency data may be transmitted to the system controller 300 where it can be processed as feedback in controlling or adjusting a parameter involved in processing a wafer 112 within the process chamber 110.

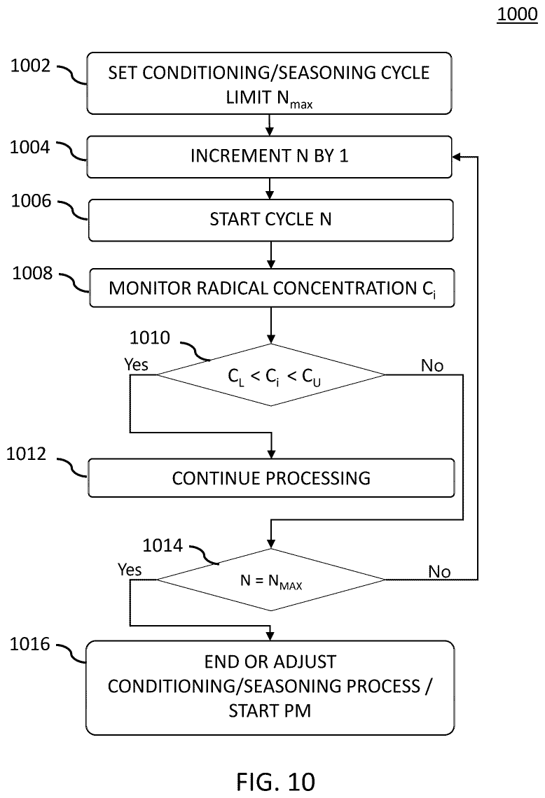

In another embodiment, the radical data obtained by monitoring the radical particle concentration (e.g., using the RPM 120 according to any of the embodiments discussed above) is further processed (e.g., by the radical monitor controller 126 or the system controller 300, each generically referred to as a “controller”) to estimate whether a conditioning or seasoning process, or other process, should be performed on the semiconductor processing system. For example, with reference to FIG. 9, a process 900 includes an initial step of enabling a process monitoring algorithm 900 within the controller (902) and setting, obtaining or otherwise enabling access to a set of radical concentration thresholds (904).

The set of radical concentration thresholds includes at least one control threshold (e.g., an upper control threshold, C_{U}, and a lower control threshold C_{L}), at least one failure threshold (e.g., an upper failure threshold, C_{FU}, and a lower failure threshold, C_{FL}), or the like or any combination thereof. Generally, however, the set of radical concentration thresholds includes at least one upper threshold (e.g., one or both of the upper control threshold, C_{U}, and the upper failure threshold, C_{FU}) and one lower threshold (e.g., one or both of the lower control threshold, C_{L}, and the lower failure threshold, C_{FL}). Where the upper control threshold, C_{U}, and the upper failure threshold, C_{FU} are used, the upper control threshold, C_{U}, is typically lower than the upper failure threshold, C_{FU}. Likewise, where the lower control threshold, C_{L}, and the lower failure threshold, C_{LU} are used, the lower control threshold, C_{L}, is typically higher than the lower failure threshold, C_{LU}. These thresholds may be stored in memory associated with, or otherwise accessible via, the controller as threshold data.

One or more processes may then be carried out within the process chamber 110 (906) and the radical particle concentration may be monitored (e.g., as described above) during the processing (908). Generally, examples of processes that can be performed at step 906 can include a deposition process, an etching process, or the like or any combination thereof. Radical data generated by the controller at step 908 may then be compared (e.g., at the controller) to the threshold data to determine the relationship between the radical concentration in a current sample of gas, Cᵢ, relative to one or more of the aforementioned radical concentration thresholds.

In one example embodiment, and as indicated by dashed-arrow 901, the radical data generated at step 908 is compared (e.g., at the controller) to the threshold data to determine whether the radical concentration in the current sample of gas, Cᵢ, is below the lower failure threshold C_{FL} or above the upper failure threshold C_{FU} (910). If the radical concentration in the current sample of gas, Cᵢ, is below the lower failure threshold C_{FL} or above the upper failure threshold C_{FU}, then the controller outputs a halt signal (912). In one embodiment, the halt signal is manifested as a signal that is output to the various components of the semiconductor processing system, and results in the components modifying their operations to stop the processing started at 906. Additionally or alternatively, the halt signal is manifested as a signal to generate and render a message (e.g., via the user interface 302 or remote system 308) indicating that the processing started at 906 should stop. Additionally or alternatively, the halt signal is manifested as a signal to generate and render a message (e.g., via the user interface 302 or remote system 308) indicating that preventative maintenance should be performed on one or more components of the semiconductor processing system, that one or more components of the semiconductor processing system should be repaired or replaced, or the like or any combination thereof. If the radical concentration in the current sample of gas, Cᵢ, is not below the lower failure threshold C_{FL} and is not above the upper failure threshold C_{FU}, then the controller compares the radical data to the threshold data to determine whether the radical concentration in the current sample of gas, Cᵢ, is above the upper control threshold C_{U}. (914). In an alternative example embodiment, and as indicated by dashed-arrow 903, the radical data generated at step 908 is compared (e.g., at the controller) to the threshold data to make the determination at step 914 (i.e., whether the radical concentration in the current sample of gas, Cᵢ, is above the upper control threshold C_{U}).

If the concentration in the current sample of gas, Cᵢ, is determined at step 914 to be above the upper control threshold C_{U}, then the controller outputs a halt signal. (916). In one embodiment, the halt signal is manifested as a signal that is output to the various components of the semiconductor processing system, and results in the components modifying their operations to stop the processing started at 906. Additionally or alternatively, the halt signal is manifested as a signal to generate and render a message (e.g., via the user interface 302 or remote system 308) indicating that the processing started at 906 should stop. Additionally or alternatively, the halt signal is manifested as a signal to generate and render a message (e.g., via the user interface 302 or remote system 308) indicating that some parameter of the processing started at 906 should be adjusted (e.g., radical delivery should be reduced or the upper control threshold C_{U} should be revised). Additionally or alternatively, the halt signal is manifested as a control signal output to one or more components of the semiconductor processing system to adjust some parameter of the processing started at 906. For example, the halt signal can be manifested as a control signal output to the radical source 115 or 116) to adjust the operation of the radical source 115 or 116 to decrease generation of the radicals, or to adjust one or more other plasma parameters such as power, flow, pressure, temperature, or the like or any combination thereof. Additionally or alternatively, the halt signal is manifested as a signal that initiates a chamber recovery process (e.g., comprising of one or more cleaning processes, one or more conditioning/seasoning processes, one or more chamber passivation processes, or the like or a combination thereof). Additionally or alternatively, the halt signal is manifested as a signal to generate and render a message (e.g., via the user interface 302 or remote system 308) indicating that a chamber recovery process should be performed.

If the radical concentration in the current sample of gas, Cᵢ, is not above the upper control threshold C_{U}, then the controller compares the radical data to the threshold data to determine whether the radical concentration in the current sample of gas, Cᵢ, is below the lower control threshold C_{L}. (918) If the radical concentration in the current sample of gas, Cᵢ, is below the lower control threshold C_{L}, then the controller outputs a halt signal. (920). In one embodiment, the halt signal is manifested as a signal to that is output to the various components of the semiconductor processing system, and results in the components modifying their operations to stop the processing started at 906. Additionally or alternatively, the halt signal is manifested as a control signal output to one or more components of the semiconductor processing system to adjust some parameter of the processing started at 906. Additionally or alternatively, the halt signal is manifested as a signal that initiates a chamber recovery process (e.g., comprising of one or more cleaning processes, one or more conditioning/seasoning processes, or the like or a combination thereof). Additionally or alternatively, the halt signal is manifested as a signal to generate and render a message (e.g., via the user interface 302 or remote system 308) indicating that a chamber recovery process should be performed. The processing started at 906 may be adjusted at 920 in a manner that is the same as, or different from, the manner that the processing started at 906 can be adjusted at 916. Likewise, the chamber recovery process to be initiated or indicated at 920 may be the same as, or different from the chamber recovery process to be initiated or indicated at 916.

If the radical concentration in the current sample of gas, Cᵢ, is not below the lower control threshold C_{L}, then the processing at step 906 continues.

As mentioned above, a chamber recovery process can include one or more conditioning/seasoning processes. Referring to FIG. 10, a conditioning or seasoning process according to one embodiment, such as process 1000, can begin with setting the cycle limit, Nₘₐₓ, indicating the maximum number of conditioning/seasoning cycles that should be performed before preventative maintenance should be performed on one or more components of the semiconductor processing system. The cycle limit, Nₘₐₓ, can be stored in memory associated with, or otherwise accessible via, the controller. At 1004, the current cycle number, N, is incremented by one. The current cycle number, N, can be a value that is stored in memory associated with, or otherwise accessible via, the controller. It should be appreciated that, if no conditioning/seasoning cycles have been started (e.g., since preventative activities were last performed or otherwise), then N would initially be zero, and step 1004 would result in incrementing the value of the current cycle number from zero to one. Next, a cycle of any known or otherwise suitable conditioning/seasoning process is started. (1006). In one embodiment, the conditioning/seasoning process may be performed as described in U.S. Patent App. Pub. No. 2022/01454591, which is incorporated herein by reference.

After the conditioning/seasoning process of the N^{th} cycle is performed, processing such as described above with respect to step 906 in FIG. 9 may be performed, and the radical particle concentration may be monitored (e.g., as described above with respect to step 908 shown in FIG. 9). (1008). Radical data generated at step 1008 is compared (e.g., at the controller) to the threshold data to determine whether the radical concentration in a current sample of gas, Cᵢ, is between the lower control threshold C_{L} and upper control threshold C_{U} (1010). If the radical concentration in the current sample of gas, Cᵢ, is between the lower control threshold C_{L} and upper control threshold C_{U}, then the processing started after 1006 is permitted to the continue (1012).

If, at 1010, it is determined that the radical concentration in the current sample of gas, Cᵢ, is not between the lower control threshold C_{L} and upper control threshold C_{U}, then the controller determines whether the current cycle number, N, equals the cycle limit, Nₘₐₓ. (1014). If the current cycle number, N, is determined to not equal the cycle limit, Nₘₐₓ, then the process reverts back to step 1004.

If, at 1014, the current cycle number, N, equals the cycle limit, Nₘₐₓ, then the controller outputs a halt signal (1016). In one embodiment, the halt signal is manifested as a signal that is output to the various components of the semiconductor processing system, and results in the components modifying their operations to stop the conditioning/seasoning process cycle started at 1006. Additionally or alternatively, the halt signal is manifested as a signal to generate and render a message (e.g., via the user interface 302 or remote system 308) indicating that the conditioning/seasoning process cycle started at 1006 should stop. Additionally or alternatively, the halt signal is manifested as a signal to generate and render a message (e.g., via the user interface 302 or remote system 308) indicating that some parameter of the conditioning/seasoning cycle started at 1006 should be adjusted. Additionally or alternatively, the halt signal is manifested as a control signal output to one or more components of the semiconductor processing system to adjust some parameter of the conditioning/seasoning cycle started at 1006. Additionally or alternatively, the halt signal is manifested as a signal to generate and render a message (e.g., via the user interface 302 or remote system 308) indicating that preventative maintenance should be performed on one or more components of the semiconductor processing system, that one or more components of the semiconductor processing system should be repaired or replaced, or the like or any combination thereof.

### IV. Conclusion

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. For example, although the radical sensing capabilities have been described above as supporting quantitative monitoring and analysis of radicals present within the semiconductor system, it will be appreciated that the radical sensing capabilities described herein may support qualitative analyses, and the radical data generated as described above may be combined with data obtained from any of the aforementioned auxiliary systems, auxiliary sensors, or from observations obtained upon inspecting wafers (device wafers, dummy wafers, etc.), or the like or any combination thereof. In another example, although the RPM 120 has been described above as including a mass spectrometer 122 (and its associated components), it will be appreciated that the RPM 120 may alternatively or additionally include any other suitable spectrometer (e.g., an optical emission spectrometer, a laser absorption spectrometer (LAS), an optical absorption spectrometer (OAS), a laser-induced fluorescence (LIF) spectrometer, a Fourier transform infrared (FTIR) spectrometer, a tunable filter spectrometer, or the like). In another example, although the radical monitor controller 126 has been described above as configured to generate radical data representing information such as type and quantity of radical ions in the gas, it will be appreciated that the radical monitor controller 126 can additionally or alternatively be configured to generate radical data representing information such as the concentration of radical particles within the gas, the partial pressure of radicals in the gas, the ratio of radical particles to other (non-radical) particles within the gas, or the like or any combination thereof.

Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

What is claimed is:

1. An apparatus, comprising:
a controller for use with a radical particle monitor operative to measure a concentration of radical particles within a gas sample obtained from a location within a semiconductor processing system having a process chamber while a process is being performed within the process chamber, the controller configured to:
obtain radical data corresponding to a measured concentration of radical particles;
compare the obtained radical data to at least one threshold; and
output a first control signal when a result of the comparing indicates that the obtained radical data has a predetermined relationship with the at least one threshold, wherein the first control signal is configured to cause a chamber recovery process to be performed within the process chamber or indicate that a chamber recovery process should be performed within the process chamber.

2. The apparatus of claim 1, further comprising the radical particle monitor.

3. The apparatus of claim 2, wherein the radical particle monitor includes at least one selected from the group consisting of a mass spectrometer, an optical emission spectrometer, and a laser absorption spectrometer (LAS), an optical absorption spectrometer (OAS), a laser-induced fluorescence (LIF) spectrometer, a Fourier transform infrared (FTIR) spectrometer, and a tunable filter spectrometer.

4. The apparatus of claim 1, wherein the radical data represents at least one selected from the group consisting of the quantity of radical particles, the concentration of radical particles, the type of radical particles, the partial pressure of radical particles, the ratio of radical particles to non-radical particles.

5. The apparatus of claim 1, wherein the obtained radical data has a predetermined relationship with the at least one threshold when the obtained radical data indicates that the measured concentration is greater than an upper threshold concentration.

6. The apparatus of claim 1, wherein the obtained radical data has a predetermined relationship with the at least one threshold when the obtained radical data indicates that the measured concentration is less than a lower threshold concentration.

7. The apparatus of claim 1, wherein the chamber recovery process includes a chamber cleaning process.

8. The apparatus of claim 1, wherein the chamber recovery process includes a chamber seasoning process.

9. The apparatus of claim 8, wherein the controller is further configured to:
obtain a cycle limit, Nₘₐₓ, indicating a maximum number of chamber seasoning processes should be performed before preventative maintenance should be performed on one or more components of the semiconductor processing system;
determine whether a current cycle number, N, indicating the number of chamber seasoning processes that has been performed since a preventative maintenance activity was last performed, is equal to the cycle limit, Nₘₐₓ; and
output the first control signal when a result of the comparing indicates that the obtained radical data does not have the predetermined relationship with the at least one threshold and when the current cycle number, N, is determined not to be equal to the cycle limit, Nₘₐₓ.

10. The apparatus of claim 9, wherein the controller is further configured to output a halt signal when the current cycle number, N, is determined to be equal to the cycle limit, Nₘₐₓ, wherein the halt signal is configured to indicate that a preventative maintenance activity should be performed.

11. The apparatus of claim 1, wherein the controller comprises:
at least one processor; and
memory accessible to the at least one processor, the memory having instructions stored thereon which, when executed by the at least one processor, cause the controller to perform the acts recited in claim 1.

12. Tangible computer-readable media having instructions stored thereon which, when executed by a processor of a controller according to claim 1, causes the controller to perform the acts recited therein.

13. A method, comprising:
measuring a concentration of radical particles within a gas sample obtained from a location within a semiconductor processing system having a process chamber while a process is being performed within the process chamber;
obtaining radical data corresponding to the measured concentration of radical particles;
comparing the obtained radical data to at least one threshold; and
outputting a first control signal when a result of the comparing indicates that the obtained radical data has a predetermined relationship with the at least one threshold, wherein the first control signal is configured to cause a chamber recovery process to be performed within the process chamber or indicate that a chamber recovery process should be performed within the process chamber.

14. The method of claim 13, wherein the radical data represents the type of radical particles in the measured concentration, the quantity of radical particles in the measured concentration.

15. The method of claim 13, wherein the obtained radical data has a predetermined relationship with the at least one threshold when the obtained radical data indicates that the measured concentration is greater than an upper threshold concentration.

16. The method of claim 13, wherein the obtained radical data has a predetermined relationship with the at least one threshold when the obtained radical data indicates that the measured concentration is less than a lower threshold concentration.

17. The method of claim 13, wherein the chamber recovery process includes a chamber cleaning process or a chamber passivation process.

18. The method of claim 13, wherein the chamber recovery process includes a chamber seasoning process.

19. The method of claim 18, further comprising:
obtaining a cycle limit, Nₘₐₓ, indicating a maximum number of chamber seasoning processes should be performed before preventative maintenance should be performed on one or more components of the semiconductor processing system;
determining whether a current cycle number, N, indicating the number of chamber seasoning processes that has been performed since a preventative maintenance activity was last performed, is equal to the cycle limit, Nₘₐₓ; and
outputting the first control signal when a result of the comparing indicates that the obtained radical data does not have the predetermined relationship with the at least one threshold and when the current cycle number, N, is determined not to be equal to the cycle limit, Nₘₐₓ.

20. The method of claim 19, further comprising outputting a halt signal when the current cycle number, N, is determined to be equal to the cycle limit, Nₘₐₓ, wherein the halt signal is configured to indicate that a preventative maintenance activity should be performed.
